(19) United States
(12) Patent Application Publication
(10) Pub. No.: US 2017/0114475 A1
(43) Pub. Date: Apr. 27, 2017

(54) METHOD FOR REMOVING WORK-AFFECTED LAYER ON SiC SEED CRYSTAL, SiC SEED CRYSTAL, AND SiC SUBSTRATE MANUFACTURING METHOD

(71) Applicant: TOYO TANSO CO., LTD., Osaka-shi, Osaka (JP)

(72) Inventors: Norihito Yabuki, Kanonji-shi (JP); Satoshi Torimi, Kanonji-shi (JP); Satoru Nogami, Kanonji-shi (JP)

(73) Assignee: TOYO TANSO CO., LTD., Osaka-shi, Osaka (JP)

(21) Appl. No.: 15/300,597

(22) PCT Filed: Mar. 10, 2015
(86) PCT No.: PCT/JP2015/001302

§ 371 Date: Sep. 29, 2016

(30) Foreign Application Priority Data
Mar. 31, 2014 (JP) 2014-074742

(51) Int. Cl. C30B 19/12; C30B 29/36; C30B 19/04

(52) U.S. Cl. CPC C30B 19/12; C30B 19/04; C30B 29/36

(57) ABSTRACT

Provided is a method in which the rate of growth is lowered even when a cut SiC seed crystal is used in performing MSE process. A SiC seed crystal that is used as a seed crystal in metastable solvent epitaxy process (MSE process) is heated under Si atmosphere and the surface of the SiC seed crystal is etched to remove a work-affected layer that was formed by cutting. Work-affected layers generated on SiC seed crystals are known to inhibit growth during MSE process, and therefore removing the work-affected layers can prevent lowering of the rate of growth.

### TECHNICAL FIELD

The present invention mainly relates to a method for removing a work-affected layer of a SiC seed crystal manufactured by cutting.

### BACKGROUND ART

SiC which is superior to Si, etc., in terms of heat resistance, electrical characteristics, and the like, has been attracting attention as a new semiconductor material. To manufacture a semiconductor element, firstly, a SiC substrate (SiC bulk substrate) is manufactured by using a seed crystal made of a SiC single crystal. Next, an epitaxial wafer is manufactured by causing a growth of an epitaxial layer on the SiC substrate. The semiconductor element is manufactured by the epitaxial wafer. A MSE process has been known as a method for causing the growth of the SiC single crystal using the seed crystal.

Patent Document 1 discloses a method for causing the growth of a SiC single crystal using MSE process. MSE process uses a SiC seed crystal made of the SiC single crystal, a feed substrate having a higher free energy than that of the SiC seed substrate, and Si melt. The SiC seed crystal and the feed substrate are arranged opposed to each other and the Si melt is interposed therebetween. Then, a heat treatment is performed in a vacuum, thus causing the growth of the SiC single crystal on a surface of the SiC seed crystal.

Non-Patent Document 1 discloses that the growth of the SIC single crystal by MSE process is hindered by crystal defects. In Non-patent Document 1, the threading screw dislocation (TSD) has the largest rate of hindrance to the growth, the basal plane dislocation (BPD) has a small rate of hindrance to the growth, and the threading edge dislocation (TED) hardly hinders the growth.

Patent Document 2 discloses a treatment method for removing a surface modified layer formed on the SiC substrate. Patent Document 2 describes that the surface modified layer is a damage layer of a crystal structure occurred in a step of manufacturing the SiC substrate (mechanical processing such as mechanical polishing). Patent Document 2 describes hydrogen etching as a method for removing the surface modified layer.

### PRIOR-ART DOCUMENTS

### Patent Documents

PATENT DOCUMENT 1: Japanese Patent Application Laid-Open No. 2008-230946

PATENT DOCUMENT 2: International Publication WO 2011/024931

### Non-Patent Documents

NON-PATENT DOCUMENT 1: Shinkichi Hamada and five others, “Dislocation conversion mechanisms by MSE growth ”, Spring Proceedings of Applied Physics, The Japan Society of Applied Physics, Mar. 11, 2013, 60th volume

### SUMMARY OF THE INVENTION

### Problems to be Solved by the Invention

The applicant has founded that the rate of growth is extremely lowered if MSE process performed using a SiC single crystal, as a SiC seed crystal, which is cut by a diamond saw or the like. MSE process is expected because a high-quality SiC substrate can be manufactured by MSE process rather than the sublimation-recrystallization process. Therefore, the problem needs to be overcome.

Patent Document 2 discloses that a work-affected layer exists in the SiC substrate which is grown from the SiC seed crystal, and the work-affected layer is removed. The work-affected layer of the SiC seed crystal is not described in Patent Document 2.

The present invention has been made in view of the circumstances described above, and a primary object of the present invention is to provide a method for preventing the rate of growth from lowering when MSE process is performed using a cut SiC seed crystal.

### Means for Solving the Problems and Effects Thereof

Problems to be solved by the present invention are as described above, and next, means for solving the problems and effects thereof will be described.

In a first aspect of the present invention, a method for removing a work-affected layer that is caused by cutting in a SiC single crystal used as a seed crystal in a metastable solvent epitaxy process, the method including an etching step of etching by heating a surface of the SiC seed crystal under Si atmosphere, is provided.

Accordingly, the work-affected layer as hindrance to the growth of MSE process can be removed, which can prevent lowering of the rate of growth of MSE process.

In the method for removing the work-affected layer of the SiC seed crystal, the SiC seed crystal has a plate-like shape. In the etching step, at least the surface parallel to the thickness direction in the SiC seed crystal is preferably etched.

Accordingly, a portion where the work-affected layer may be occurred can be surely removed, which can further surely prevent lowering of the rate of growth in MSE process.

In the method for removing the work-affected layer of the SiC seed crystal, the amount of etching in the etching step is preferably 10 μm or more.

This can improve the rate of growth in MSE process.

In a second aspect of the present invention, a SiC seed crystal in which the work-affected layer is removed by the above-described step of removing the work-affected layer of the SiC seed crystal is provided.

This can achieve the SiC seed crystal capable of causing the growth of the SiC single crystal at a stable rate of growth by MSE process.

In a third aspect of the present invention, a method for manufacturing a SiC substrate including the above-described removal step of removing the work-affected layer of the SiC seed crystal and its growth step is provided. In the growth step, the SiC single crystal is grown by the metastable solvent epitaxy process using the SiC seed crystal in which the work-affected layer is removed in the removal step.

Accordingly, the rate of growth in MSE process is not lowered, which can efficiently manufacture the SiC substrate.

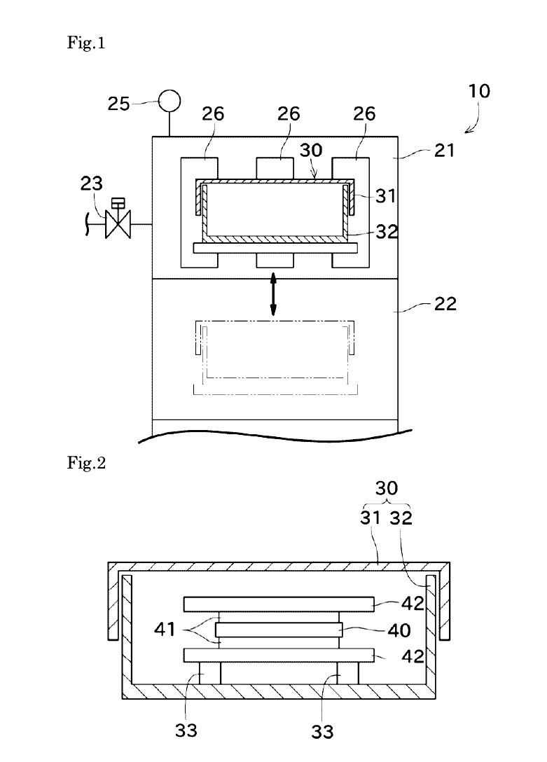

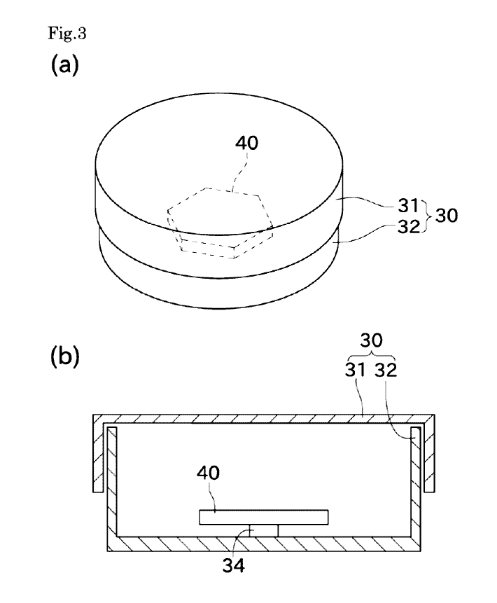

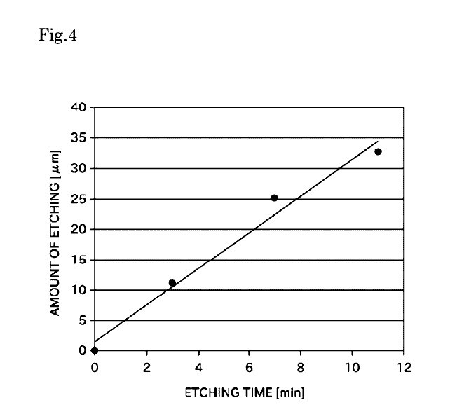

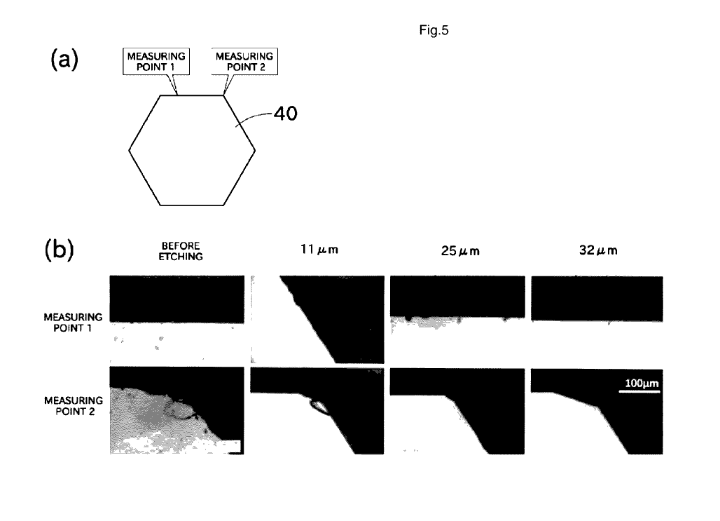

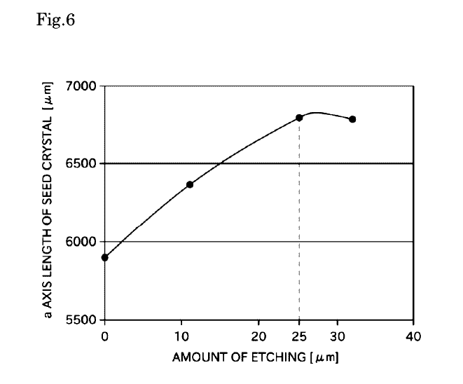

### BRIEF DESCRIPTION OF THE DRAWINGS

[FIG. 1] A diagram for illustration of an outline of a high-temperature vacuum furnace for use in etching of a SiC seed crystal according to the present invention.

[FIG. 2] A schematic view showing a configuration example when a SiC single crystal is grown by MSE process.

[FIG. 3] A perspective view and a cross-sectional view showing a situation when the SiC seed crystal is etched.

[FIG. 4] A graph showing the time of etching and the amount of etching in the SiC seed crystal.

[FIG. 5] Diagrams explaining a change of a surface form of the SiC seed crystal depending on the time of etching.

[FIG. 6] A graph showing a relationship between the amount of etching in the SiC seed crystal and the rate of growth in MSE process.

### EMBODIMENT FOR CARRYING OUT THE INVENTION

Next, an embodiment of the present invention will be described with reference to the drawings.

Firstly, referring to FIG. 1, a high-temperature vacuum furnace 10 for use in heat treatment (etching) of this embodiment will be described. FIG. 1 is a diagram for illustration of an outline of a high-temperature vacuum furnace for use in a surface treatment method of the present invention.

As shown in FIG. 1, the high-temperature vacuum furnace 10 includes a main heating chamber 21 and a preheating chamber 22. The main heating chamber 21 is configured to heat an object to be treated that is made of, at least in its surface, SiC single crystal, up to a temperature of 1000° C. or more and 2300° C. or less. The preheating chamber 22 is a space for preheating prior to heating the object to be treated in the main heating chamber 21.

A vacuum-forming valve 23, an inert gas injection valve 24, and a vacuum gauge 25 are connected to the main heating chamber 21. The vacuum-forming valve 23 is configured to adjust the degree of vacuum of the main heating chamber 21. The vacuum gauge 25 is configured to measure the degree of vacuum of the interior of the main heating chamber 21.

Heaters 26 are provided in the main heating chamber 21. Heat reflection metal plates (not shown) are secured to side walls and a ceiling of the main heating chamber 21. The heat reflection metal plates are configured to reflect heat of the heaters 26 toward a central region of the main heating chamber 21. This provides strong and uniform heating of a SiC substrate 40, to cause a temperature rise up to 1000° C. or more and 2300° C. or less. Examples of the heaters 26 include, for example, resistive heaters and high-frequency induction heaters.

The object to be treated is heated while stored in a crucible (storing container) 30. The crucible 30 is placed on an appropriate support or the like, and the support is movable at least in a range from the preheating chamber to the main heating chamber.

The crucible 30 includes an upper container 31 and a lower container 32 that are fittable with each other. The crucible 30 is made of tantalum metal, and includes a tantalum carbide layer that is exposed to an internal space of the crucible 30. Si as a Si supply source with proper form is placed in the crucible 30.

To perform a heat treatment on the object to be treated, as indicated by a chain line in FIG. 1, the crucible 30 is placed in the preheating chamber 22 of the high-temperature vacuum furnace 10, and preheated at a proper temperature (for example, about 800° C.). Then, the crucible 30 is moved into the main heating chamber 21 in which the temperature has been preliminarily raised to a set temperature (for example, about 1800° C.), whereby the object to be treated is heated. The preheating may be omitted.

Next, a method for manufacturing the SiC substrate by the growth of the SiC single crystal from the SiC seed crystal using MSE process will be described. FIG. 2 is a schematic view showing a configuration example when the SiC single crystal is grown by MSE process.

As shown in FIG. 2 a SiC seed crystal 40, two Si plates 41 and two carbon feed substrates 42 are placed within the crucible 30. They are supported by a support 33.

The SiC seed crystal 40 is used as a substrate (seed-side member). The SiC seed crystal 40 is manufactured by dicing (cutting) of a 4H—SiC single crystal having a predetermined size, for example. As shown in FIG. 3, the SiC seed crystal 40 of this embodiment is a hexagonal plate-like member, but any shape is adoptable. 6H—SiC may be used instead of 4H—SiC. Si plates 41 are placed above and below the SiC seed crystal 40.

The Si plates 41 are plate-like members made of Si. The melting point of Si is about 1400° C., and therefore the Si plates 41 are melted by heating in the above-described high-temperature vacuum furnace 10. Carbon feed substrates 42 are placed above and below the Si plates 41.

The carbon feed substrates 42 are used as a material for supplying carbon, that is, as a feed-side. The carbon feed substrates 42 made of polycrystalline 3C—SiC, has a higher free energy than that of the SiC seed crystal 40.

The SiC seed crystal 40, the Si plates 41, and the carbon feed substrates 42 are placed as described above, and then heated at 1800° C., for example. Then, the Si plates 41 placed between the SiC seed crystal 40 and the carbon feed substrates 42 are melted and thereby a silicon melt is worked as a solvent for moving carbon.

Accordingly, the growth of the SiC single crystal by MSE process can be caused on the surface of the SiC seed crystal 40. This can manufacture the SiC substrate that is planar at the atomic level with less micropipe and crystal defects. For the SiC substrate, a step of causing the growth of an epitaxial layer by CVD process (chemical vapor deposition process). LPE process (liquid-phase epitaxial process) or the like, a step of implanting ions, an annealing step of activating ions, etc. are performed to manufacture a semiconductor element.

The applicant has founded that the rate of growth of the SiC single crystal may be extremely lowered when MSE process is performed using the SiC seed crystal 40. Moreover, the applicant has also founded that this phenomenon is occurred when using the SiC seed crystal 40 which is manufactured by cutting such as dicing. Based on the findings, the applicant has considered that a work-affected layer is occurred by applying stress to the SiC seed crystal 40 at a time of cutting and the growth of the crystal is hindered by the work-affected layer. Then, the applicant has proposed a method for removing the work-affected layer.

Specifically, the method is for removing the work-affected layer by heating the surface of the SiC seed crystal 40 under Si atmosphere and then etching, prior to performing MSE process. The method will be described with reference to FIG. 3. FIG. 3 contains a perspective view and a cross-sectional view showing a situation when the SiC seed crystal 40 is etched.

The SiC seed crystal 40 is etched by heating the crucible 30 storing the SiC seed crystal 40 therein, in the high-temperature vacuum furnace 10. As shown in FIG. 3, the SiC seed crystal 40 is placed within the above-described crucible 30. In this embodiment, the SiC seed crystal 40 is supported by a support 34, but the support 34 may be omitted. The portion where the work-affected layer of the SiC seed crystal 40 would be occurred, that is, on and near a side surface (a surface parallel to the thickness direction) of the SiC seed crystal 40 is preferably kept exposed.

As described above, Si supply source is placed within the crucible 30 for causing Si atmosphere within the crucible 30 at a time of heating. Solid Si pellets, Si adhered to inner walls within the crucible 30, or the inner walls made of tantalum silicide may be used as Si supply source. The etching can be performed by heating the crucible 30 (the SiC seed crystal 40) under an environment of 1500° C. or more and 2200° C. or less, desirably 1800° C. or more and 2000° C. or less. After heating, Si supply source causes Si atmosphere within the crucible 30.

As a result of heating the SiC seed crystal 40 under Si vapor pressure, SiC of the SiC seed crystal 40 is sublimated into Si₂C or SiC₂ and Si under Si atmosphere and C are bonded on the surface of the SiC seed crystal 40. This leads to self-organization. Accordingly, the work-affected layer that would be occurred on a side surface of the SiC seed crystal and near the side surface can be removed. This can prevent lowering of the rate of growth when performing MSE process, even in the SiC seed crystal 40 manufactured by cutting such as dicing.

Next, an experiment performed by the applicant in order to confirm the effect of the above-described method will be described with reference to FIG. 4 to FIG. 6.

FIG. 4 and FIG. 5 are drawings showing a result when the SiC seed crystal 40 is etched. In this experiment, four SiC seed crystals 40 having the same configuration were prepared, and three of them were heated at 1800° C., 10⁻⁵ Pa, for three minutes, seven minutes and eleven minutes respectively.

As shown in FIG. 4, as a result of heat treatment, the amount of etching was 11 μm in the SiC seed crystal 40 after heating for three minutes, the amount of etching was 25 μm in the SiC seed crystal 40 after heating for seven minutes, and the amount of etching is 32 μm in the SiC seed crystal 40 after heating for eleven minutes. The amount of etching was increased as the etching time gets longer. There was a proportional connection between the etching time and the amount of etching. Thus, measuring the etching time enables the desirable amount of etching to be performed to the SiC seed crystal 40.

FIG. 5 contains photomicrographs as seen from the top (from one side of the thickness direction). As shown in FIG. 5 (a), a measuring point 1 represents a side of hexagon, and a measuring point 2 represents a vertex of hexagon. The number written in an upper portion of FIG. 5 (b) shows the amount of etching. As shown in photomicrographs, especially the photomicrograph of the measuring point 2, roughness caused by partially chipping was occurred on an end portion of the SiC seed crystal 40. As the SiC seed crystal 40 had larger amount of etching, chip in the end portion was further removed. The significant improvement could be seen in the amount of etching of 10 μm. In the amount of etching of 25 μm and 32 μm it could be seen that chip in the end portion was substantially completely removed and its end surface was planarized.

Next, an experiment about a relationship between the amount of etching and the rate of growth will be described with reference to FIG. 6. In this experiment, as described in FIG. 2, the Si plates 41 and carbon feed substrates 42 were placed and then heated for a predetermined time, at 1800° C., with the inert gas pressure of 10 torr. Then, the SiC seed crystal 40 was taken out, and the length in a axis direction (epitaxial growth direction) was measured.

It can be seen that, in FIG. 6, as the amount of etching is larger, the length in a axis direction of the SiC seed crystal 40 is longer (that is, the rate of growth is higher). Specifically, the rate of growth in the SiC seed crystal 40 having the amount of etching of 10 μm was clearly higher than the rate of growth in the SiC seed crystal 40 without etching. Furthermore, the rate of growth in the SiC seed crystal 40 having the amount of etching of 25 μm was higher. Both of cases that the etching amount was 25 μm and 32 μm in the SiC seed crystal 40, the rate of growth was almost the same.

According to the experiment, the amount of etching is preferably 10 μm or more, more preferably, the amount of etching is 25 μm or more. Thus, etching of the SiC seed crystal 40 can prevent lowering of the rate of growth in MSE process.

The work-affected layer of the seed crystal has not been removed conventionally, but generally, chemical mechanical polishing, hydrogen etching or the like are used as a method for removing the work-affected layer of the SiC substrate (SiC bulk substrate). However, although performing chemical mechanical polishing can easily polish an upper surface or lower surface of the SiC seed crystal 40, it is difficult to polish a side surface of the SiC seed crystal 40. Moreover, the rate of polishing in chemical mechanical polishing is 1 μm/h or less, and the rate of etching in hydrogen etching is several tens of nm/h to several hundreds of nm/h. Therefore, it takes a lot of time in a conventional method for removing the work-affected layer.

In this respect, as it can be seen in the result shown in FIG. 4, in etching by heating under Si vapor pressure (under Si atmosphere), the rate of etching is 3 μm/min to 4 μm/min. Therefore, the work-affected layer of the SiC seed crystal 40 can be removed in a short time.

As described above, in this embodiment, the SiC seed crystal 40 that is manufactured by dicing and used as a seed crystal in MSE process is heated under Si atmosphere and thereby its surface is etched. Then, the work-affected layer formed the SiC seed crystal 40 is removed.

Accordingly, since the work-affected layer that hinders the growth of MSE process can be removed, lowering of the rate of growth can be prevented.

In this embodiment, in the SiC seed crystal 40 having a plate-like shape, at least its surface parallel to the thickness direction in the SiC seed crystal 40 is etched.

Accordingly, a portion in which the work-affected layer would be formed can be surely removed. This can further surely prevent lowering of the rate of growth.

Although a preferred embodiment of the present invention has been described above, the above-described configuration can be modified, for example, as follows.

In controlling the amount of etching, not only the etching time but also the temperature, the inert gas pressure, the Si pressure and the like may be used.

The above-described temperature condition, the pressure condition and the like, are merely illustrative, and they are appropriately changeable. Moreover, a heating apparatus other than the above-described high-temperature vacuum furnace 10 is adoptable, and a container having a shape or material different from the crucible 30 is adoptable.

An appropriate method for cutting may be mechanical processing such as dicing, the processing by energy wave such as laser processing, or the like.

### DESCRIPTION OF THE REFERENCE NUMERALS

10 high-temperature vacuum furnace

30 crucible

40 SiC seed crystal

41 Si plate

42 carbon feed substrate

1. A method for removing a work-affected layer of a SiC seed crystal, the work-affected layer caused by cutting, in a SiC single crystal used as a seed crystal in metastable solvent epitaxy process, the method comprising:
an etching step of etching a surface of the SiC seed crystal by heating under Si atmosphere.

2. The method for removing the work-affected layer of the SiC seed crystal according to claim 1, wherein
the SiC seed crystal has a plate-like shape,
in the etching step, at least a surface parallel to a thickness direction of the SiC seed crystal is etched.

3. The method for removing the work-affected layer of the SiC seed crystal according to claim 1, wherein
in the etching step, the amount of etching is 10 μm or more.

4. A SiC seed crystal in which the work-affected layer is removed by the method for removing the work-affected layer of the SiC seed crystal according to claim 1.

5. A method for manufacturing a SiC substrate, the method comprising:
a removal step of removing the work-affected layer of the SiC seed crystal by the method for removing the work-affected layer of the SiC seed crystal according to claim 1; and
a growth step of causing the growth of the SiC single crystal by metastable solvent epitaxy process, using the SiC seed crystal in which the work-affected layer is removed in the removal step.
